(19) United States
(12) Patent Application Publication
(10) Pub. No.: US 2025/0386692 A1
(43) Pub. Date: Dec. 18, 2025

(54) DISPLAY APPARATUS

(71) Applicant: LG Display Co., Ltd., Seoul (KR)

(72) Inventors: Hakmin LEE, Paju-si (KR); Hoonsok SON, Paju-si (KR); Minki KIM, Paju-si (KR)

(73) Assignee: LG Display Co., Ltd., Seoul (KR)

(21) Appl. No.: 19/190,163

(22) Filed: Apr. 25, 2025

(30) Foreign Application Priority Data
Jun. 17, 2024 (KR) 10-2024-0078160

(51) Int. Cl. H10K 59/131; H10K 59/121; H10K 59/123; H10K 59/126; H10K 59/80; H10K 102/00

(52) U.S. Cl. CPC H10K 59/131; H10K 59/1213; H10K 59/123; H10K 59/126; H10K 59/80518; H10K 2102/341

(57) ABSTRACT

A display apparatus according to one embodiment of the present specification includes a substrate including a display area including a plurality of pixels, and a pad area near the display area, a pad disposed on the substrate in the pad area and provided as a plurality of pads, and a light shielding layer disposed between a plurality of adjacent pads.

### CROSS REFERENCE TO RELATED APPLICATION

The present application claims priority to Korean Patent Application No. 10-2024-0078160, filed Jun. 17, 2024, the entire contents of which is incorporated herein for all purposes by this reference.

### BACKGROUND

### Technical Field

The present specification relates to a display apparatus.

### Description of the Related Art

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle and a higher contrast ratio, and can be lighter and thinner and has lower power consumption than the LCD apparatus because it does not require a separate backlight. In addition, there is an advantage in that the OLED display apparatus can drive at a low voltage, have a fast response time, and especially have the inexpensive manufacturing cost.

Recently, demand for a display apparatus that requires augmented reality (AR), virtual reality (VR), or equivalent ultra-high resolution using such an OLED display apparatus is increasing.

### BRIEF SUMMARY

The present specification is directed to providing a display apparatus in which it is possible to suppress or prevent a short circuit defect between adjacent pads.

The present specification is also directed to providing a display apparatus in which it is possible to suppress or prevent thin film encapsulation (TFE) around a pad from being torn.

The present specification is also directed to providing a display apparatus in which it is possible to suppress or prevent damage to TFE due to an etching laser and minimize the TFE around a pad from being torn even when using high-transmittance TFE, thereby suppressing or preventing a short circuit defect between adjacent pads.

The present specification is also directed to providing a display apparatus in which it is possible to suppress or prevent damage to TFE due to an etching laser even when using high-transmittance TFE, thereby ensuring reliability of a pad part.

Technical benefits of the present specification are not limited to the above-described benefits, and other technical benefits may be inferred from the following embodiments.

According to one embodiment of the present specification, there is provided a display apparatus including a substrate including a display area including a plurality of pixels, and a pad area near the display area, a pad disposed on the substrate in the pad area and provided as a plurality of pads, and a light shielding layer disposed between a plurality of adjacent pads.

According to another embodiment of the present specification, there is provided a display apparatus including a substrate including a pad area, a plurality of pads disposed on the substrate in the pad area, a light shielding layer disposed around the plurality of pads in the pad area, a flexible film including a lead electrode overlapping the plurality of pads and electrically connected to the plurality of pads, and an anisotropic conductive film disposed between the substrate and the flexible film, wherein the anisotropic conductive film comes into direct contact with the light shielding layer.

Detailed matters of other embodiments are included in detailed description and accompanying drawings.

According to the embodiments of the present specification, it is possible to suppress or prevent a short circuit defect between adjacent pads.

According to the embodiments of the present specification, it is possible to suppress or prevent thin film encapsulation (TFE) around the pad from being torn.

According to the embodiments of the present specification, it is possible to minimize TFE around the pad from being torn and suppress or prevent damage to the TFE due to an etching laser even when using high-transmittance TFE, thereby suppressing or preventing a short circuit defect between adjacent pads.

According to the embodiments of the present specification, it is possible to suppress or prevent damage to TFE due to an etching laser even when using high-transmittance TFE, thereby ensuring reliability of a pad part.

According to the embodiments of the present specification, it is possible to prevent a short circuit defect between adjacent pads, thereby suppressing or preventing reliability of the pad part of the display apparatus from being reduced, and furthermore, to enable the operation defect prevention, life extension, and the like of the display apparatus, thereby reducing production energy.

However, effects obtainable from the present specification are not limited to the above-described effects, and other effects that are not mentioned will be able to be clearly understood by those skilled in the art to which the present specification pertains from the following description.

### BRIEF DESCRIPTION OF THE SEVERAL VIEWS OF THE DRAWINGS

FIG. 1 is a plan view of a display apparatus according to one embodiment.

FIG. 2 is an enlarged view of the periphery of a sub-pixel in FIG. 1.

FIG. 3 is a cross-sectional view along line A-A′ in FIG. 2.

FIG. 4 is a cross-sectional view along line B-B′ in FIG. 2.

FIG. 5 is a cross-sectional view along line C-C′ in FIG. 2.

FIG. 6 is an enlarged view of area Q1 in FIG. 1.

FIG. 7 is a cross-sectional view along line D-D′ in FIG. 6.

FIG. 8 is a cross-sectional view along line E-E′ in FIG. 6.

FIGS. 9 to 13 are cross-sectional views for each process in a method of manufacturing a display apparatus according to one embodiment.

FIG. 14 is a cross-sectional view of a display apparatus according to another embodiment.

FIG. 15 is a cross-sectional view of a display apparatus according to still another embodiment.

FIGS. 16 to 18 are views illustrating a process of manufacturing the display apparatus according to the embodiment of FIG. 15.

FIG. 19 is a cross-sectional view of a display apparatus according to yet another embodiment.

FIG. 20 is a cross-sectional view of a display apparatus according to yet another embodiment.

FIG. 21 is an enlarged view of a pad area of a display apparatus according to yet another embodiment.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween. To elaborate, “connected” and “coupled” are intended to have the broadest possible meaning. Specifically, the phrase “A is connected to B” encompasses both a direct connection-where no intervening components or elements are present-and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” should be interpreted in the same manner.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals indicate the same components. In addition, for some embodiments in the drawings, thicknesses, proportions, and dimensions of components may be exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

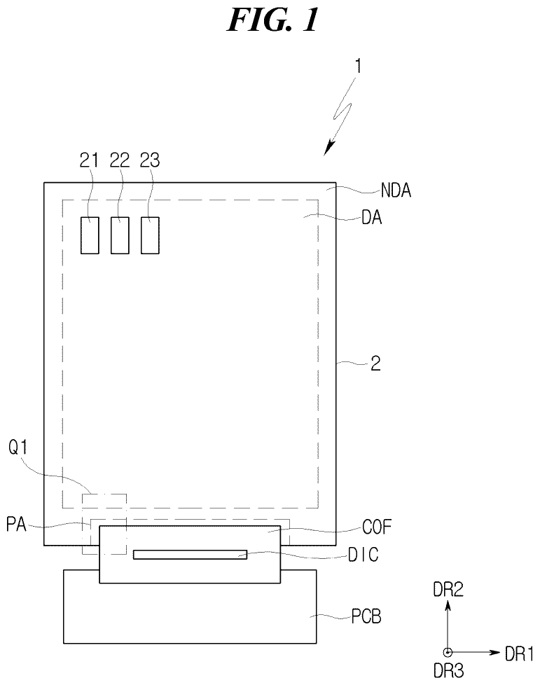

FIG. 1 is a plan view of a display apparatus according to one embodiment.

Referring to FIG. 1, a display apparatus 1 may include a display area DA and a non-display area NDA. The display area DA may be an area in which light is emitted to the outside to display a screen. The non-display area NDA may be an area in which light is not emitted to the outside so as not to display a screen.

The non-display area NDA may be located around the display area DA. The non-display area NDA may surround the display area DA, but the embodiments of the present specification are not limited thereto. A bezel area of the display apparatus 1 may be defined by the non-display area NDA, but the embodiments of the present specification are not limited thereto.

The display apparatus 1 may include a plurality of sub-pixels 21, 22, and 23. The plurality of sub-pixels 21, 22, and 23 may be disposed in the display area DA.

The plurality of sub-pixels 21, 22, and 23 may be formed on a substrate 2. The plurality of sub-pixels 21, 22, and 23 may form one pixel. The plurality of pixels may be formed on the substrate 2.

The plurality of sub-pixels 21, 22, and 23 include a first sub-pixel 21, a second sub-pixel 22, and a third sub-pixel 23. Since the first sub-pixel 21, the second sub-pixel 22, and the third sub-pixel 23 may be arranged sequentially, the second sub-pixel 22 may be disposed adjacent to one side, for example, the right side of the first sub-pixel 21, and the third sub-pixel 23 may be disposed adjacent to one side, for example, the left side of the second sub-pixel 22.

Throughout the present specification, when two sub-pixels are disposed adjacent to each other, it should be construed to mean that no other sub-pixels are disposed between the two sub-pixels.

The first sub-pixel 21 may be provided to emit red (R) light, the second sub-pixel 22 may be provided to emit blue (B) light, and the third sub-pixel 23 may be provided to emit green (G) light, but the embodiments of the present specification are not necessarily limited thereto.

FIG. 1 illustrates an example in which a pixel includes only three sub-pixels 21, 22, and 23, but the present specification is not limited thereto, and the pixel may include four sub-pixels. When the pixel includes four sub-pixels, the pixel may further include a fourth sub-pixel provided to emit white (W) light.

Each of the first to third sub-pixels 21, 22, and 23 may be provided to have the same size. For example, each of the first to third sub-pixels 21, 22, and 23 may be provided to have the same width and the same height.

Here, the width may refer to a horizontal direction (a first direction DR1) based on FIG. 1, and the height may refer to a direction (a second direction DR2) perpendicular to the width based on FIG. 1, but the present specification is not necessarily limited thereto. The first direction DR1 may intersect the second direction DR2, and a third direction DR3 may intersect the first direction DR1 and the second direction DR2. The third direction DR3 may refer to a thickness direction of the display apparatus 1, but is not limited thereto.

The first direction DR1, the second direction DR2, and the third direction DR3 should be understood as relative directions and are not limited to embodiments of the present specification.

The display apparatus 1 may further include a pad area PA. The pad area PA may be disposed in the non-display area NDA. In FIG. 1, the pad area PA is illustrated as being disposed under the display area DA (at one side of the display area DA in the second direction DR2), but is not limited thereto. The pad area PA may be disposed at the other side of the display area DA in the second direction DR2 or disposed at one side and/or the other side of the display area DA in the first direction DR1.

The display apparatus 1 may further include a printed circuit board PCB, a flexible film COF, and a drive IC DIC.

The printed circuit board PCB may be connected to the sub-pixels 21, 22, and 23 and the like on the substrate 2 through the flexible film COF. The printed circuit board PCB may be electrically connected to the flexible film COF. Although not illustrated, the printed circuit board PCB and the flexible film COF may be electrically connected through a plurality of pads.

The printed circuit board PCB may have various types of components for supplying various signals, such as a driving signal, a data signal, and the like, to the drive IC DIC.

FIG. 1 illustrates a single printed circuit board PCB, but the embodiments of the present specification are not limited thereto, and the number of printed circuit boards PCBs may vary according to a design.

At least a part of the flexible film COF may be disposed in the non-display area NDA. The flexible film COF may be electrically connected to the pad area PA. The flexible film COF may supply driving signals, power voltages, data voltages, and the like to the plurality of sub-pixels 21, 22, and 23 of the display area DA and driving circuits.

The flexible film COF may be a flexible insulating film. The flexible film COF may include, for example, polycarbonate, polyethylene terephthalate, polyimide, polyamide, polyester, polyacrylate, polymethyl methacrylate, or the like, but is not limited thereto.

The drive IC DIC may be mounted on the flexible film COF. The drive IC DIC may be disposed by a method of a chip on glass, a chip on film, a tape carrier package, or the like according to a mounting method. In the present disclosure, the drive IC DIC is described as being mounted on the flexible film COF by the chip on film method, but is not limited thereto.

The drive IC DIC may drive the display apparatus 1. The drive IC DIC may process data signals for displaying a video, various driving signals for processing the data signals, and the like. The drive IC DIC may include a gate driver IC, a data driver IC, and the like.

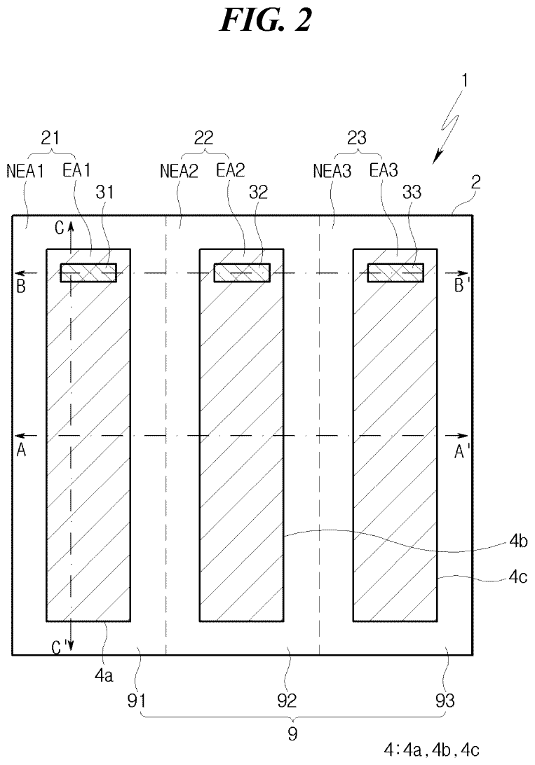

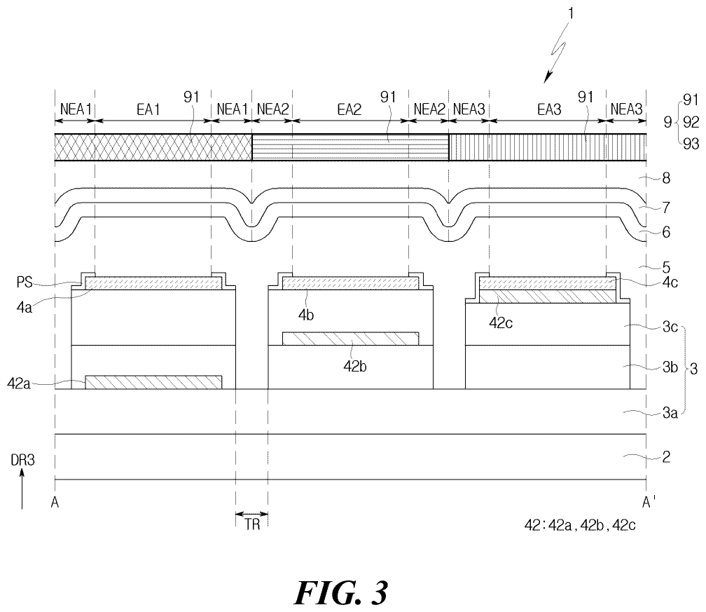

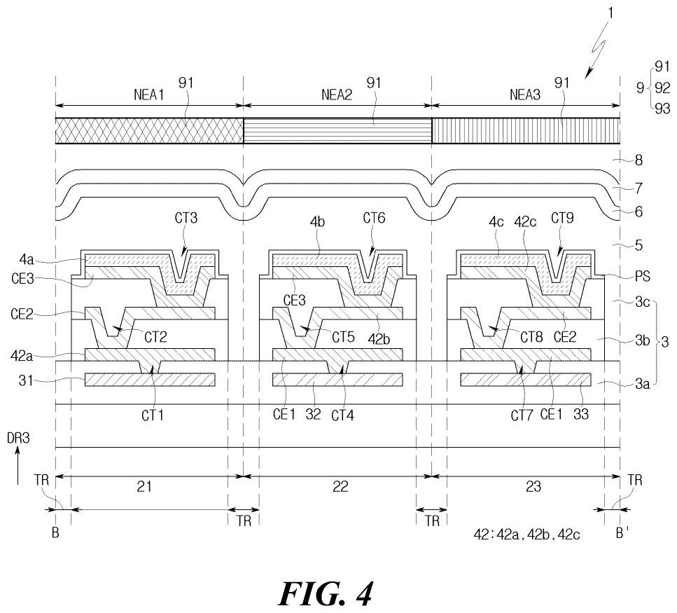

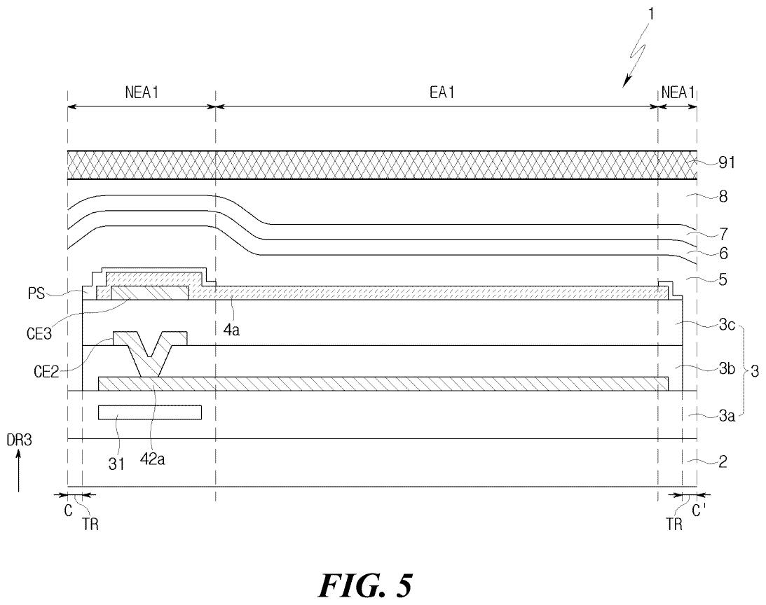

FIG. 2 is an enlarged view of the periphery of a sub-pixel in FIG. 1. FIG. 3 is a cross-sectional view along line A-A′ in FIG. 2. FIG. 4 is a cross-sectional view along line B-B′ in FIG. 2. FIG. 5 is a cross-sectional view along line C-C′ in FIG. 1.

Referring to FIGS. 2 to 5, the display apparatus 1 according to one embodiment may include the substrate 2, the insulating layer 3 (3a, 3b, and 3c), an anode electrode layer 4 (4a, 4b, and 4c), a protective layer PS (or a bank), a common emission layer 5, a cathode electrode 6, a capping layer 7, an encapsulation layer 8, and a color filter layer 9.

Each sub-pixel 21, 22, or 23 may include an emission area EA1, EA2, or EA3 and a non-emission area NEA1, NEA2, or NEA3. The first sub-pixel 21 may include a first emission area EA1 and a first non-emission area NEA1 around the first emission area EA1, the second sub-pixel 22 may include a second emission area EA2 and a second non-emission area NEA2 around the second emission area EA2, and the third sub-pixel 23 may include a third emission area EA3 and a third non-emission area NEA3 around the third emission area EA3.

The display apparatus 1 may further include transistors 31, 32, and 33. The transistors 31, 32, and 33 may be disposed in the non-emission areas NEA1, NEA2, and NEA3 of the sub-pixels 21, 22, and 23, respectively. For example, the transistors 31, 32, and 33 may be located at the other sides of reflective electrodes 42a, 42b, and 42c in the second direction DR2, but are not limited thereto.

The transistors 31, 32, and 33 may be disposed in the emission areas EA1, EA2, and EA3 and disposed under the reflective electrodes 42a, 42b, and 42c, and in this case, the transistors 31, 32, and 33 cannot be visible from the outside.

The anode electrode layers 4a, 4b, and 4c may be electrically connected to the corresponding transistors 31, 32, and 33 through connection electrodes CE (CE1, CE2, and CE3), the reflective electrodes 42a, 42b, and 42c, and contact holes CT (CT1 to CT9) that are disposed in the sub-pixels 21, 22, and 23, respectively.

A trench TR may be disposed between the sub-pixels 21, 22, and 23 (or between the emission areas EA1, EA2, and EA3 of the sub-pixels 21, 22, and 23. The trench TR may be defined by a second insulating layer 3b and a third insulating layer 3c. The trench TR may be formed in a groove or recess shape in which the second insulating layer 3b and the third insulating layer 3c are removed to expose a first insulating layer 3a. The trench TR may be defined by a side surface of the second insulating layer 3b, a side surface of the third insulating layer 3c, and an upper surface of the first insulating layer 3a, but is not limited thereto.

The trench TR may extend in the first direction DR1 and the second direction DR2. The trench TR extending in the first direction DR1 may intersect the trench TR extending in the second direction DR2.

Since the trench TR is disposed between the sub-pixels 21, 22, and 23, even when the common emission layer 5 and the cathode electrode 6 are disposed throughout the sub-pixels 21, 22, and 23 without distinction of the sub-pixels 21, 22, and 23, it is possible to prevent a leakage current between the sub-pixels 21, 22, and 23 and prevent a short circuit between a charge generation layer of the common emission layer 5 and the cathode electrode 6, thereby preventing light color mixing.

The substrate 2 may be a plastic film, a glass substrate, or a semiconductor substrate, such as made of silicon.

The substrate 2 may be formed of a transparent material or an opaque material. The first sub-pixel 21, the second sub-pixel 22, and the third sub-pixel 23 are provided on the substrate 2. The first sub-pixel 21 may be provided to emit red (R) light, the second sub-pixel 22 may be provided to emit blue (B) light, and the third sub-pixel 23 may be provided to emit green (G) light.

Since the display apparatus 1 according to one embodiment is configured in a so-called top emission type in which emitted light is emitted upward, both a transparent material and an opaque material may be used as a material of the substrate 2. Color filters 91, 92, and 93 may be respectively provided above the first to third sub-pixels 21, 22, and 23 from which light is emitted to transmit light of the above colors.

The display area DA, the non-display area NDA, the pad area PA, the emission area EA, and the non-emission area NEA may be defined on the substrate 2. That is, the substrate 2 may include the display area DA, the non-display area NDA, the pad area PA, the emission area EA, and the non-emission area NEA.

The insulating layer 3 is formed on the substrate 2. The insulating layer 3 may include a plurality of insulating layers 3a, 3b, and 3c. Hereinafter, the insulating layer 3 is described as including the first to third insulating layers 3a, 3b, and 3c, but is not limited thereto, and an additional insulating layer may be further disposed between the first to third insulating layers 3a, 3b, and 3c.

The first insulating layer 3a is disposed on the substrate 2, and circuit elements including the plurality of thin film transistors 31, 32, and 33, various signal lines, capacitors, and the like are provided in the first insulating layer 3a of each sub-pixel 21, 22, or 23. The signal lines may include a gate line, a data line, a power line, and a reference line, and the thin film transistors 31, 32, and 33 may include a switching thin film transistor, a driving thin film transistor, and a sensing thin film transistor. Each of the sub-pixels 21, 22, and 23 is defined by an intersection structure of gate lines and data lines.

The switching thin film transistor serves to supply the driving thin film transistor with a data voltage switched according to a gate signal supplied to the gate line and supplied from the data line.

The driving thin film transistor is switched according to the data voltage supplied from the switching thin film transistor to generate a data current from a power source supplied from the power line and supply the data current to the anode electrode layer 4.

The sensing thin film transistor serves to detect a threshold voltage deviation of the driving thin film transistor, which causes the degradation of image quality, and supplies the current of the driving thin film transistor to the reference line in response to a sensing control signal supplied from the gate line or a separate sensing line.

The capacitor serves to maintain the data voltage supplied to the driving thin film transistor for one frame and is connected to each of a gate terminal and a source terminal of the driving thin film transistor.

A first transistor 31, a second transistor 32, and a third transistor 33 are respectively disposed in the sub-pixels 21, 22, and 23 in the first insulating layer 3a. The first transistor 31 may be connected to the first anode electrode 4a disposed on the first sub-pixel 21 to apply a driving voltage for emitting light of a color corresponding to the first sub-pixel 21.

The second transistor 32 may be connected to the second anode electrode 4b disposed on the second sub-pixel 22 to apply a driving voltage for emitting light of a color corresponding to the second sub-pixel 22.

The third transistor 33 may be connected to the third anode electrode 4c disposed on the third sub-pixel 23 to apply a driving voltage for emitting light of a color corresponding to the third sub-pixel 23.

When receiving the gate signal from the gate line using each of the transistors 31, 32, and 33, each of the first sub-pixel 21, the second sub-pixel 22, and the third sub-pixel 23 supplies a predetermined current to the emission layer according to the data voltage of the data line. Accordingly, the emission layer of each of the first sub-pixel 21, the second sub-pixel 22, and the third sub-pixel 23 may emit light with a predetermined brightness according to the predetermined current.

The first insulating layer 3a may protect the transistors 31, 32, and 33. The first insulating layer 3a may be formed of an inorganic insulating material, but is not necessarily limited thereto and may be formed of an organic insulating material. The transistors 31, 32, and 33 may be located in the first insulating layer 3a. For example, the first insulating layer 3a may be formed of an inorganic material, such as silicon nitride (SiNₓ), silicon oxide (SiOₓ), aluminum oxide (Al₂O₃), or the like, but the embodiments of the present specification are not limited thereto.

The second insulating layer 3b may be disposed on the first insulating layer 3a. For example, the second insulating layer 3b may be formed of an inorganic material, such as silicon nitride (SiNₓ), silicon oxide (SiOₓ), aluminum oxide Al₂O₃), or the like, but the embodiments of the present specification are not limited thereto.

The third insulating layer 3c may be disposed on the second insulating layer 3b. For example, the third insulating layer 3c may be formed of an inorganic material, such as silicon nitride (SiNₓ), silicon oxide (SiOₓ), aluminum oxide Al₂O₃), or the like, but the embodiments of the present specification are not limited thereto.

However, the embodiments of the present specification are not limited thereto, and an additional insulating layer may be further disposed between the insulating layers 3a, 3b, and 3c.

The anode electrode layer 4 is patterned for each sub-pixel 21, 22, or 23. For example, one anode electrode layer 4 may be formed in the first sub-pixel 21, another anode electrode layer 4 may be formed in the second sub-pixel 22, and still another anode electrode layer 4 may be formed in the third sub-pixel 23.

That is, the anode electrode layer 4 may include a first anode electrode 4a, a second anode electrode 4b, and a third anode electrode 4c separately. Each of the first anode electrode 4a, the second anode electrode 4b, and the third anode electrode 4c may be disposed in each sub-pixel 21, 22, or 23. The anode electrode layer 4 may serve as an anode of the display apparatus 1.

The display apparatus 1 may further include the reflective electrode 42 (42a, 42b, and 42c) having different surface heights. By providing the reflective electrode 42 (42a, 42b, and 42c) having different surface heights, it is possible to further increase light extraction efficiency using a micro-cavity characteristic.

The micro-cavity characteristic refers to a characteristic that, when a distance between the reflective electrode 42 and the cathode electrode 6 is an integer multiple of a half wavelength (λ/2) of light emitted from a sub-pixel, constructive interference occurs to amplify the light, and when a reflection and re-reflection process is repeated between the reflective electrode 42 and the cathode electrode 6, a degree of amplified light continuously increases, thereby increasing the external extraction efficiency of light.

The reflective electrode 42 may include a first reflective electrode 42a disposed in the first sub-pixel 21, a second reflective electrode 42b disposed in the second sub-pixel 22, and a third reflective electrode 42c disposed in the third sub-pixel 23.

In the first sub-pixel 21, the first insulating layer 3a, the first transistor 31 disposed in the first insulating layer 3a, a first reflective electrode 42a disposed on the first insulating layer 3a, the second insulating layer 3b disposed on the first reflective electrode 42a, a second connection electrode CE2 disposed on the second insulating layer 3b, the third insulating layer 3c disposed on the second connection electrode CE2, a third connection electrode CE3 disposed on the third insulating layer 3c, the first anode electrode 4a disposed on the third connection electrode CE3, and the protective layer PS disposed on the first anode electrode 4a may be disposed sequentially on the substrate 2.

In the first sub-pixel 21, the first reflective electrode 42a may be patterned and disposed across the first emission area EA1 and the first non-emission area NEA1. In the first sub-pixel 21, the second connection electrode CE2 and the third connection electrode CE3 may be patterned and disposed in the first non-emission area NEA1.

In the second sub-pixel 22, the first insulating layer 3a, the first transistor 31 disposed in the first insulating layer 3a, the first connection electrode CE1 disposed on the first insulating layer 3a, the second insulating layer 3b disposed on the first connection electrode CE1, a second reflective electrode 42b disposed on the second insulating layer 3b, the third insulating layer 3c disposed on the second reflective electrode 42b, the third connection electrode CE3 disposed on the third insulating layer 3c, the second anode electrode 4b disposed on the third connection electrode CE3, and the protective layer PS disposed on the second anode electrode 4b may be disposed sequentially on the substrate 2.

In the second sub-pixel 22, the second reflective electrode 42b may be patterned and disposed across the second emission area EA2 and the second non-emission area NEA2. In the second sub-pixel 22, the first connection electrode CE1 and the third connection electrode CE3 may be patterned and disposed in the second non-emission area NEA2.

In the third sub-pixel 23, the first insulating layer 3a, the first transistor 31 disposed in the first insulating layer 3a, the first connection electrode CE1 disposed on the first insulating layer 3a, the second insulating layer 3b disposed on the first connection electrode CE1, the second connection electrode CE2 disposed on the second insulating layer 3b, the third insulating layer 3c disposed on the second connection electrode CE2, a third reflective electrode 42c disposed on the third insulating layer 3c, the third anode electrode 4c disposed on the third reflective electrode 42c, and the protective layer PS disposed on the third anode electrode 4c may be disposed sequentially on the substrate 2.

In the third sub-pixel 23, the third reflective electrode 42c may be patterned and disposed across the third emission area EA3 and the third non-emission area NEA3. In the third sub-pixel 23, the first connection electrode CE1 and the second connection electrode CE2 may be patterned and disposed in the third non-emission area NEA3.

The first reflective electrode 42a disposed in the first sub-pixel 21 and the first connection electrode CE1 disposed in the second sub-pixel 22 and the third sub-pixel 23 may each be disposed separately, but may be formed on the same layer, may include the same material, and may be formed by the same process, but are not limited thereto.

The second reflective electrode 42b disposed in the second sub-pixel 22 and the second connection electrode CE2 disposed in the first sub-pixel 21 and the third sub-pixel 23 may each be disposed separately, but may be formed on the same layer, may include the same material, and may be formed by the same process, but are not limited thereto.

The third reflective electrode 42c disposed in the third sub-pixel 23 and the third connection electrode CE3 disposed in the first sub-pixel 21 and the second sub-pixel 22 may each be disposed separately, but may be formed on the same layer, may include the same material, and may be formed by the same process, but are not limited thereto.

In the non-emission areas NEA1, NEA2, and NEA3, the contact hole CT (CT1 to CT9) may be defined by passing through the first to third insulating layers 3a to 3c in the thickness direction, and in the sub-pixels 21, 22, and 23, the contact holes CT (CT1 to CT9) may electrically connect the transistors 31, 32, and 33 to the anode electrode layer 4 (4a, 4b, and 4c).

A first contact hole CT1 may be defined by the first insulating layer 3a in the first emission area EA1. The first contact hole CT1 may pass through the first insulating layer 3a in the thickness direction (the third direction DR3) to expose the first transistor 31. In the first emission area EA1, the first reflective electrode 42a may come into contact with the first transistor 31 through the first contact hole CT1.

A second contact hole CT2 may be defined by the second insulating layer 3b in the first emission area EA1. The second contact hole CT2 may pass through the second insulating layer 3b in the thickness direction (the third direction DR3) to expose the first reflective electrode 42a. In the first emission area EA1, the second connection electrode CE2 may come into contact with the first reflective electrode 42a through the second contact hole CT2.

A third contact hole CT3 may be defined by the third insulating layer 3c in the first emission area EA1. The third contact hole CT3 may pass through the third insulating layer 3c in the thickness direction (the third direction DR3) to expose the second connection electrode CE2. In the first emission area EA1, the third connection electrode CE3 may come into contact with the second connection electrode CE2 through the third contact hole CT3.

A fourth contact hole CT4 may be defined by the first insulating layer 3a in the second emission area EA2. The fourth contact hole CT4 may pass through the first insulating layer 3a in the thickness direction (the third direction DR3) to expose the second transistor 32. In the second emission area EA2, the first connection electrode CE1 may come into contact with the second transistor 32 through the fourth contact hole CT4.

A fifth contact hole CT5 may be defined by the second insulating layer 3b in the second emission area EA2. The fifth contact hole CT5 may pass through the second insulating layer 3b in the thickness direction (the third direction DR3) to expose the first connection electrode CE1. In the second emission area EA2, the second reflective electrode 42b may come into contact with the first connection electrode CE1 through the fifth contact hole CT5.

A sixth contact hole CT6 may be defined by the third insulating layer 3c in the second emission area EA2. The sixth contact hole CT6 may pass through the third insulating layer 3c in the thickness direction (the third direction DR3) to expose the second reflective electrode 42b. In the second emission area EA2, the third connection electrode CE3 may come into contact with the second reflective electrode 42b through the sixth contact hole CT6.

A seventh contact hole CT7 may be defined by the first insulating layer 3a in the third emission area EA3. The seventh contact hole CT7 may pass through the first insulating layer 3a in the thickness direction (the third direction DR3) to expose the third transistor 33. In the third emission area EA3, the first connection electrode CE1 may come into contact with the third transistor 33 through the seventh contact hole CT7.

An eighth contact hole CT8 may be defined by the second insulating layer 3b in the third emission area EA3. The eighth contact hole CT8 may pass through the second insulating layer 3b in the thickness direction (the third direction DR3) to expose the first connection electrode CE1. In the third emission area EA3, the second connection electrode CE2 may come into contact with the first connection electrode CE1 through the eighth contact hole CT8.

A ninth contact hole CT9 may be defined by the third insulating layer 3c in the third emission area EA3. The ninth contact hole CT9 may pass through the third insulating layer 3c in the thickness direction (the third direction DR3) to expose the second connection electrode CE2. In the third emission area EA3, the third reflective electrode 42c may come into contact with the second connection electrode CE2 through the ninth contact hole CT9.

As described above, the transistors 31, 32, and 33, the connection electrodes CE1, CE2, and CE3, and the reflective electrodes 42a, 42b, and 42c have been described as coming into direct contact with one another through the contact holes CT (CT1 to Ct9), but the embodiments of the present specification are not limited thereto. For example, each contact hole CT (CT1 to CT9) may be filled with a separate contact layer (not illustrated), and the transistors 31, 32, and 33, the connection electrodes CE1, CE2, and CE3, and the reflective electrodes 42a, 42b, and 42c may be electrically connected by contact layers filling the contact holes CT (CT1 to CT9). Here, the contact layer (not illustrated) may be formed of tungsten or the like.

The reflective electrodes 42 (42a, 42b, and 42c) may reflect light, which is emitted toward the reflective electrode 42 among light emitted from the common emission layer 5 of the sub-pixel 21, 22, and 23, toward the cathode electrode 6 or the encapsulation layer 8. In addition, the reflective electrode 42 is formed to implement the micro-cavity characteristic through reflection and re-reflection with the cathode electrode 6. To this end, the reflective electrode 42 may include a reflective material for reflecting light. For example, the reflective material may be a metal, but is not necessarily limited thereto, and may be any other material as long as it may reflect light. For example, the reflective material may include titanium (Ti)/aluminum (Al), but is not limited thereto.

The display apparatus 1 according to one embodiment may be provided in the top emission type, and to this end, the reflective electrode 42 may be provided to reflect the light emitted from the common emission layer 5 upward.

The reflective electrode 42 may reflect light, which is emitted toward the reflective electrode 42 among the light emitted from the common emission layer 5 of each sub-pixel 21, 22, or 23, toward the cathode electrode 6 or the encapsulation layer 8. In addition, the reflective electrode 42 is formed to implement the micro-cavity characteristic through reflection and re-reflection with the cathode electrode 6. To this end, the reflective electrode 42 may include a reflective material for reflecting light.

Since the reflective electrode 42 is disposed at a relatively lower location than the common emission layer 5 for emitting light, the reflective electrode 42 may reflect the light emitted from the common emission layer 5 upward. Here, upward may refer to a direction in which a user may perceive light, for example, a side to which the encapsulation layer 8 or the color filter layer 9 is disposed. Accordingly, it is possible to further increase the light efficiency of the first sub-pixel 21, the second sub-pixel 22, and the third sub-pixel 23 compared to a case in which there is no reflective electrode 42, and the user can perceive an image with high brightness, that is, clear image, through the increased light efficiency. That is, the user can perceive a clear image.

As described above, the display apparatus 1 may have the reflective electrode 42, thereby further increasing the light extraction efficiency using the micro-cavity characteristic. The reflective electrode 42 may include the first reflective electrode 42a, the second reflective electrode 42b, and the third reflective electrode 42c.

A distance between the first reflective electrode 42a and the anode electrode layer 4 may be larger than a distance between the second reflective electrode 42b and the anode electrode layer 4. A distance between the second reflective electrode 42b and the anode electrode layer 4 may be larger than a distance between the third reflective electrode 42c and the anode electrode layer 4.

The cathode electrode 6 in the emission area EA1, EA2, or EA3 of each sub-pixel 21, 22, or 23 may be locatedon the same line. Accordingly, a size relationship between the distance between the reflective electrodes 42a, 42b, or 42c and the anode electrode layer 4 in each sub-pixel 21, 22, or 23 may be the same as a size relationship between the distance between the reflective electrode 42a, 42b, or 42c and the cathode electrode 6.

In this way, the reason why the reflective electrodes 42a, 42b, and 42c are formed to have various separation distances (or resonance distances) from the cathode electrode 6 is that the light extraction efficiency of different colors can be increased through reflection and re-reflection between the reflective electrodes 42a, 42b, and 42c and the cathode electrode 6 according to the separation distances. Accordingly, it is possible to increase the light extraction efficiency of red light in the first sub-pixel 21, increase the light extraction efficiency of green light in the second sub-pixel 22, and increase the light extraction efficiency of blue light in the third sub-pixel 23.

The connection electrodes CE1, CE2, and CE3 may be disposed in the emission areas EA1, EA2, and EA3 of the sub-pixels 21, 22, and 23. The connection electrodes CE1, CE2, and CE3 may be disposed on the same layer as the reflective electrodes 42a, 42b, and 42c and formed through the same process.

The anode electrode layer 4 is disposed on the reflective electrode 42. The anode electrode layer 4 is formed to supply holes to the common emission layer 5. The anode electrode layer 4 may be provided transparently so that light reflected from the reflective electrode 42 may proceed upward. The anode electrode layer 4 may be formed of a transparent material, but is not limited thereto, and a metal material may be formed in the form of a thin film as long as it may transmit light. For example, the anode electrode layer 4 may include titanium nitride (TiN), but is not limited thereto. The anode electrode layer 4 may be formed of a very thin film so that the light reflected from the reflective electrode 42 may proceed upward. For example, the thickness of the anode electrode layer 4 may be about 5 nm or less. For example, the thickness of the anode electrode layer 4 may be about 3 nm or less, but is not limited thereto.

The anode electrode layer 4 may come into direct contact with the reflective electrode 42 and may be electrically connected to the reflective electrode 42 or may be indirectly connected to the reflective electrode 42 through the contact hole CT and electrically connected to the reflective electrode 42. The reflective electrode 42 may be electrically connected to each of the first to third transistors 31, 32, and 33 through another contact hole CT so that a driving voltage provided by each of the first to third transistors 31, 32, and 33 may be applied to the anode electrode layer 4. The anode electrode layer 4 may supply holes to the common emission layer 5 when the driving voltages are applied from the first to third transistors 31, 32, and 33. In each sub-pixel 21, 22, or 23, the anode electrode layer 4 may come into direct contact with the third reflective electrode 42c.

The anode electrode layer 4 may be disposed in each of the first to third sub-pixels 21, 22, and 23 to have substantially the same height from an upper surface of the reflective electrode 42, the connection electrode CE, or the insulating layer 3.

The protective layer PS may be disposed on the anode electrode layer 4. The protective layer PS may be formed of an inorganic material, such as silicon nitride (SiNₓ), silicon oxide (SiOₓ), aluminum oxide (Al₂O₃), or the like, but the embodiments of the present specification are not limited thereto.

The protective layer PS may serve as a bank that defines emission areas EA1, EA2, and EA3 of the sub-pixels 21, 22, and 23. In the emission areas EA1, EA2, and EA3, the protective layer PS may define the emission areas EA1, EA2, and EA3 by exposing upper surfaces of the anode electrode layers 4 (4a, 4b, and 4c). Each emission area EA1, EA2, or EA3 may be the same as an area of the anode electrode layer 4, which is exposed from the protective layer PS.

On the other hand, in the non-emission areas NEA1, NEA2, and NEA3, the protective layer PS may cover the upper surfaces of the anode electrode layers 4a, 4b, and 4c. A protective layer PS (or a bank) may be disposed on each of the first sub-pixel 21, the second sub-pixel 22, and the third sub-pixel 23.

The protective layer PS is illustrated as being formed of a single layer, but is not limited thereto, and the protective layer PS may be formed of multiple layers. The protective layer PS may be provided to cover an edge of the anode electrode layer 4 disposed in each of the first to third sub-pixels 21, 22, and 23 to distinguish the first sub-pixel 21, the second sub-pixel 22, and the third sub-pixel 23.

The common emission layer 5 is formed on the anode electrode layer 4 and the protective layer PS. The common emission layer 5 may be formed as a common layer across the first to third sub-pixels 21, 22, and 23.

The OLED according to one embodiment may include the anode electrode layer 4 (ANO), the cathode electrode 6 (CAT), and the common emission layer 5 between the anode electrode layer 4 and the cathode electrode 6.

The common emission layer 5 may be provided to emit white (W) light. To this end, the common emission layer 5 may include a plurality of stacks for emitting light of different colors. For example, the common emission layer 5 may include a first stack, a second stack, and a charge generation layer CGL provided between the first stack and the second stack.

However, the embodiments of the present specification area not limited thereto, and the common emission layer 5 may be provided to emit white light by having a three-stack structure including a blue emission layer, a green emission layer, a red emission layer, and a charge generation layer, but is not necessarily limited thereto, and may be formed of multiple layers exceeding 3 stacks as long as it may emit white light.

The cathode electrode 6 is formed on the common emission layer 5. The cathode electrode 6 may serve as a cathode of the display apparatus 1. Like the common emission layer 5, the cathode electrode 6 is formed in each of the sub-pixels 21, 22, and 23 and between the sub-pixels 21, 22, and 23.

In the display apparatus 1 according to one embodiment, the cathode electrode 6 may be formed as a cathode electrode including a translucent material in order to implement white light with increased light efficiency in the top emission type. Accordingly, the micro-cavity effect can be obtained for each of the first to third sub-pixels 21, 22, and 23. When the cathode electrode 6 is formed as the cathode electrode including a translucent material, the micro-cavity effect can be obtained as light is reflected and re-reflected repeatedly between the cathode electrode 6 and the reflective electrode 42, thereby increasing light extraction efficiency.

In the case of a top emission type, the cathode electrode 6 may be provided as a first electrode, and in the case of a bottom emission type, the cathode electrode 6 may be provided as an opaque cathode electrode including a reflective material. In the case of the top emission type, the cathode electrode 6 may be formed as a cathode electrode including a translucent material to increase light extraction efficiency using the micro-cavity characteristic. Since the display apparatus 1 increases light extraction efficiency using the micro-cavity characteristic in the top emission type, an example in which the cathode electrode 6 is formed of a translucent material will be described.

Meanwhile, since the cathode electrode 6 is formed on the upper surface of the common emission layer 5, the cathode electrode 6 may be formed along a profile of the common emission layer 5. Since the common emission layer 5 is formed along the profile of the anode electrode layer 4 in the emission area, the cathode electrode 6 may be formed along the profile of the anode electrode layer 4. In addition, the capping layer 7 on the cathode electrode 6 may also be formed along a profile of the cathode electrode 6.

The capping layer 7 may be formed of an inorganic insulating material, but is not limited thereto. The capping layer 7 may be formed of a single layer, but is not limited thereto, and may be formed of multiple layers. The capping layer 7 may be disposed on the cathode electrode 6 to protect the OLED.

The encapsulation layer 8 is formed on the cathode electrode 6 to prevent external moisture from penetrating the common emission layer 5. The encapsulation layer 8 may be formed of an inorganic insulating material or formed in a structure in which an inorganic insulating material and an organic insulating material are alternately stacked, but is not necessarily limited thereto.

The color filter layer 9 is formed on the encapsulation layer 8. A color filter layer 9 is provided in each of the first to third sub-pixels 21, 22, and 23 to block a specific color from light emitted from the emission layer of each sub-pixel. The color filter layer 9 may include a first color filter 91 provided in the first sub-pixel 21, a second color filter 92 provided in the second sub-pixel 22, and a third color filter 93 provided in the third sub-pixel 23.

The first color filter 91 may be provided to block light of other colors excluding red (R) light. In this case, the first color filter 91 may be provided as a red color filter. The second color filter 92 may be provided to block light of other colors excluding green (G) light. In this case, the second color filter 92 may be provided as a green color filter. The third color filter 93 may be provided to block light of other colors excluding blue (B) light. In this case, the third color filter 93 may be provided as a blue color filter. However, the embodiments of the present specification are not necessarily limited thereto.

The first to third color filters 91, 92, and 93 provided in the first to third sub-pixels 21, 22, and 23, respectively, may be provided in the same size as the respective sub-pixels or provided by being reduced or expanded at a predetermined ratio to each sub-pixel.

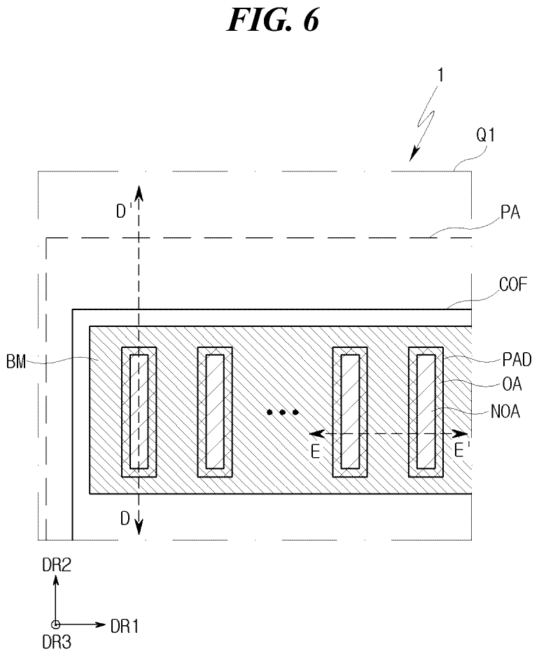

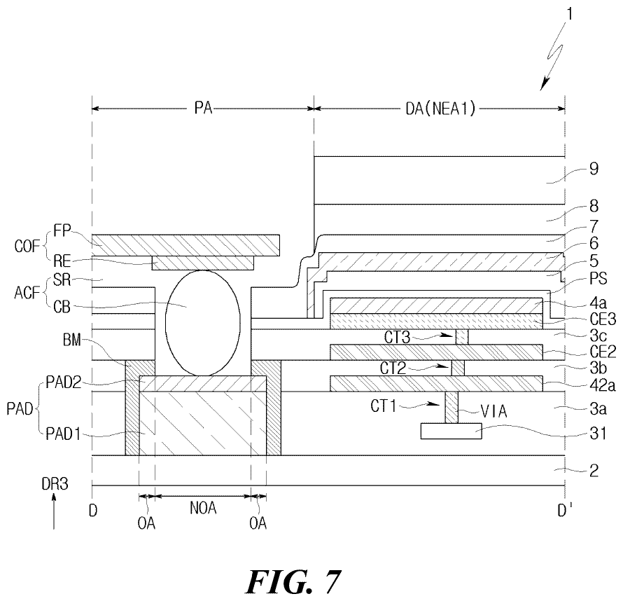

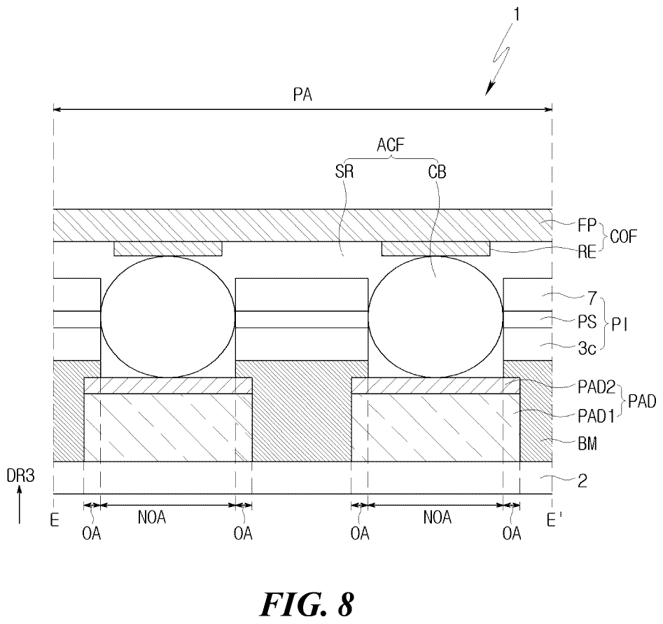

FIG. 6 is an enlarged view of area Q1 in FIG. 1. FIG. 7 is a cross-sectional view along line D-D′ in FIG. 6. FIG. 8 is a cross-sectional view along line E-E′ in FIG. 6.

Referring to FIGS. 6 to 8, the display apparatus 1 may include a plurality of pads PADs and a light shielding layer BM that are disposed in the pad area PA. The plurality of pads PADs may be repeatedly arranged in the first direction DR1. The light shielding layer BM may be disposed around the plurality of pads PADs.

Each of the plurality of pads PADs may be formed of a plurality of layers. For example, each of the plurality of pads PADs may include a first pad layer PAD1 and a second pad layer PAD2 disposed on the first pad layer PAD1.

The first pad layer PA D1 and the second pad layer PAD2 may be formed of different materials. For example, the first pad layer PAD1 may be formed of Al, and the second pad layer PAD2 may be formed of TiN, but the embodiments of the present specification are not limited thereto.

The first pad layer PAD1 may be formed of the same material as a component that fills the contact holes CTs connecting the transistors 31, 32, and 33 to the first reflective electrode 42a or the first connection electrode CE1. For example, the display apparatus 1 may further include a via VIA that fills the first contact hole CT1 to connect the first reflective electrode 42a to the first transistor 31. The first pad layer PAD1 may be formed of the same material as the via VIA, but is not limited thereto.

In the present specification, the via VIA will be described as being formed of substantially the same material as the first reflective electrode 42a. In this case, the via VIA may be formed by a part of the first reflective electrode 42a. Accordingly, in FIGS. 4 and 5, the first reflective electrode 42a and the via VIA are not separately illustrated, and the first connection electrode CE1 and the via VIA are not separately illustrated. In FIG. 7, for convenience of description, the via VIA and the first reflective electrode 42a are separately illustrated.

However, the embodiments of the present specification are not limited thereto, and the via VIA may be formed of a different material from the first reflective electrode 42a. For example, the first reflective electrode 42a may be formed of an aluminum alloy, and the via VIA may be formed of aluminum (Al).

The second pad layer PAD2 may be formed of the same material as the anode electrode layer 4. For example, the second pad layer PAD2 may include the same material as the first anode electrode 4a, but is not limited thereto.

Even when the second pad layer PAD2 includes the same material as the anode electrode layer 4, the second pad layer PAD2 may be formed by a different mask process from the anode electrode layer 4.

The second pad layer PAD2 may entirely overlap the first pad layer PAD1 in the thickness direction (the third direction DR3). Since the second pad layer PAD2 is disposed on the first pad layer PAD1, the second pad layer PAD2 can suppress or prevent external air, moisture, and the like from penetrating the first pad layer PAD1, thereby improving the reliability of the pad PAD.

The light shielding layer BM may be disposed between the plurality of pads PADs. The light shielding layer BM may be disposed between adjacent pads PADs. The light shielding layer BM may be disposed between adjacent pads PADs to cover all areas of side surfaces of the pads PADs facing each other. The light shielding layer BM may be disposed to surround the plurality of pads in a plan view, but is not limited thereto.

The light shielding layer BM may come into direct contact with the side surfaces of the plurality of pads PADs. For example, the light shielding layer BM may be disposed between the side surfaces of the pads PADs facing each other. The light shielding layer BM may be disposed between the side surfaces of the pads PAD facing each other to come into direct contact with the side surfaces of the pads PADs. However, the embodiments of the present specification are not limited thereto.

The light shielding layer BM may come into direct contact with side surfaces of the first pad layer PAD1 and side surfaces of the second pad layer PAD2. For example, the light shielding layer BM may come into direct contact with side surfaces of the adjacent first pad layers PAD Is between adjacent pads PADs. The light shielding layer BM may come into direct contact with side surfaces of the adjacent second pad layers PA D 2s between adjacent pads PAD. However, the embodiments of the present specification are not limited thereto.

A thickness of the light shielding layer BM may be equal to or larger than a thickness of the pad PAD, but is not limited thereto.

An upper surface of the light shielding layer BM may be located at a higher location than an upper surface of the pad PAD (an upper surface of the second pad layer PAD2), but is not limited thereto.

At least a part of the light shielding layer BM may overlap the pad PAD in the thickness direction (the third direction DR3) or from a plan view. The light shielding layer BM may extend from a portion in contact with the side surfaces of the pad PAD so that a part thereof may be disposed on the pad PAD.

Each of the plurality of pads PADs may include an overlapping area OA and a non-overlapping area NOA. The overlapping area OA may refer to an area in which each of the plurality of pads PADs overlaps the light shielding layer BM in the thickness direction (the third direction DR3). The non-overlapping area NOA may refer to an area in which each of the plurality of pads PADs does not overlap the light shielding layer BM in the thickness direction (the third direction DR3).

The overlapping area OA may be disposed around the non-overlapping area NOA. The overlapping area OA may be disposed outside the non-overlapping area NOA, but is not limited thereto. In at least one of the plurality of pads PADs, the overlapping area OA may be disposed to surround the non-overlapping area NOA in a plan view, but is not limited thereto.

In the overlapping area OA, the light shielding layer BM may cover the pad PAD. In the overlapping area OA, the light shielding layer BM may come into direct contact with the pad PAD. In this case, the light shielding layer BM may come into direct contact with the upper surface of the second pad layer PAD2 in the overlapping area OA.

In the non-overlapping area NOA, the light shielding layer BM may expose the pad PAD. In the non-overlapping area NOA, the light shielding layer BM may not cover the pad PAD.

A pad insulating layer PI may be disposed on the light shielding layer BM. The pad insulating layer PI may be disposed in the pad area PA.

The pad insulating layer PI may be formed by at least a part of the insulating layer 3, the protective layer PS, the capping layer 7, and the encapsulation layer 8, which are disposed in the display area DA and the non-display area NDA. For example, the pad insulating layer PI may be formed by including the third insulating layer 3c, the protective layer PS, and the capping layer 7, which are arranged in the pad area PA.

The pad insulating layer PI may overlap the entire area of the light shielding layer BM in the thickness direction (the third direction DR3), but is not limited thereto.

The light shielding layer BM may be formed of an organic material, but is not limited thereto, and may be formed of an inorganic material. The light shielding layer BM may be formed of an insulating material. The light shielding layer BM may insulate between adjacent pads PADs.

The light shielding layer BM may be formed of a material capable of absorbing and blocking an etching laser that etches the encapsulation layer 8. For example, when the etching laser is a laser having a peak wavelength of 355 nm, the light shielding layer BM may be formed of a material capable of absorbing and blocking light having a peak wavelength of 355 nm. However, the peak wavelength or wavelength of light that the light shielding layer BM may absorb is not limited thereto, and may vary according to an etching laser used.

Since the light shielding layer BM is disposed around the plurality of pads PADs and the light shielding layer BM absorbs and blocks the etching laser that etches the encapsulation layer 8, it is possible to suppress or prevent a lifting defect or tearing defect of the insulating films disposed around the plurality of pads PADs. Even when the encapsulation layer 8 has high transmittance, the light shielding layer BM may absorb and block the etching laser, thereby suppressing or preventing the lifting defect or tearing defect of the insulating films disposed around the plurality of pads PADs.

Furthermore, even when the etching laser that etches the encapsulation layer 8 is radiated, the insulating films (the light shielding layer BM and the pad insulating layer PI) around the pads PADs may be maintained, thereby suppressing or preventing a short circuit between adjacent pads PADs. Even when the encapsulation layer 8 has high transmittance, the insulating films (the light shielding layer BM and the pad insulating layer PI) around the pad PAD may be maintained, thereby suppressing or preventing a short circuit between adjacent pads PADs.

Accordingly, it is possible to suppress or prevent an operation defect of the display apparatus 1 and extend the life of the display apparatus 1.

The pad insulating layer PI may expose the non-overlapping area NOA of each of the plurality of pads PADs. The pad insulating layer PI and the light shielding layer BM may expose at least a part of each of the plurality of pads PADs. Accordingly, the plurality of pads PADs may be electrically connected to the flexible film COF.

The flexible film COF may overlap the pad area PA and overlap the plurality of pads PADs. The flexible film COF may include a flexible film board FP and a lead electrode RE.

The lead electrode RE may be disposed on the flexible film board FP. The lead electrode RE may be disposed on one surface of the flexible film board FP facing the pad PAD.

The lead electrode RE may include a conductive material. The lead electrode RE may be electrically connected to the drive IC DIC.

The lead electrode RE may be provided as a plurality of lead electrodes and disposed to correspond to each of the plurality of pads PADs. At least a part of each of the plurality of lead electrodes R Es may be disposed to overlap the plurality of pads PADs.

The flexible film board FP may be a flexible insulating film. The flexible film board FP may include, for example, polycarbonate, polyethylene terephthalate, polyimide, polyamide, polyester, polyacrylate, polymethyl methacrylate, or the like, but is not limited thereto.

The display apparatus 1 may further include an anisotropic conductive film ACF disposed between the flexible film COF and the substrate 2. The anisotropic conductive film A CF may be disposed between the pad PAD and the lead electrode RE.

Through the anisotropic conductive film ACF, the substrate 2 and the flexible film COF may be attached. Through the anisotropic conductive film ACF, the pad PAD and the lead electrode RE may be electrically connected.

The anisotropic conductive film ACF may include an adhesive member SR and a conductive ball CB. Since the adhesive member SR may be disposed between the flexible film COF and the substrate 2, the flexible film COF and the substrate 2 may be mutually adhered by the adhesive member SR.

The conductive ball CB may be disposed in the adhesive member SR. The conductive ball CB may include a conductive material. The conductive ball CB may be provided as a plurality of conductive balls.

The conductive ball CB may be disposed between the pad PAD and the lead electrode RE that overlap each other. The conductive ball CB may be disposed on the plurality of pads PADs exposed by the light shielding layer BM and the pad insulating layer PI. The conductive ball CB may be disposed in the non-overlapping area NOA.

The conductive ball CB may come into direct contact with the overlapping pad PAD and the lead electrode RE. The conductive ball CB may electrically connect the pad PAD to the lead electrode RE.

Hereinafter, a method of manufacturing the display apparatus 1 according to one embodiment will be described. While describing the method of manufacturing the display apparatus 1 according to one embodiment, description of parts already described in FIGS. 1 to 8 will be briefly given or omitted.

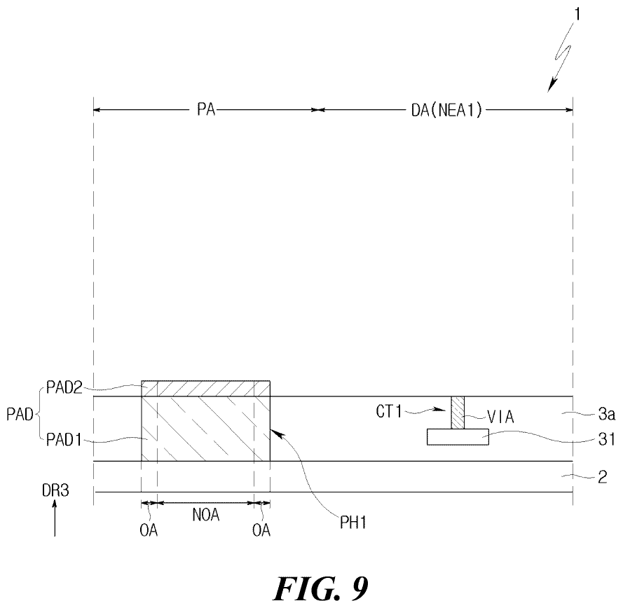

FIGS. 9 to 13 are cross-sectional views for each process in a method of manufacturing a display apparatus according to one embodiment.

FIGS. 9 to 11 illustrate the pad area PA and the first non-emission area NEA1 of the display area DA, but contents to be described below may also be applied to the second non-emission area NEA2 (see FIG. 4), the third non-emission area NEA3 (see FIG. 4), and the emission areas EA1, EA2, and EA3 (see FIG. 3) of the display area DA in the same manner.

Referring to FIG. 9, the transistor 31 and the first insulating layer 3a are formed on the substrate 2. In FIG. 9, the first insulating layer 3a is illustrated as being formed of one layer, but the first insulating layer 3a may be formed of a plurality of insulating films. The first insulating layer 3a may be disposed across the pad area PA and the display area DA.

In the first non-emission area NEA1, the first insulating layer 3a may define the first contact hole CT1. In the pad area PA, the first insulating layer 3a may define a first pad hole PH1.

The first contact hole CT1 may expose the first transistor 31. The first pad hole PH1 may expose the substrate 2, but is not limited thereto, and the first pad hole PH 1 may have a recess shape that does not expose the substrate 2.

The via VIA may fill the first contact hole CT1. The pad PAD may be disposed in the first pad hole PH1. The first pad layer PAD1 and the via VIA include the same material and may be formed by the same process. The second pad layer PAD2 may be disposed on the first pad layer PAD1.

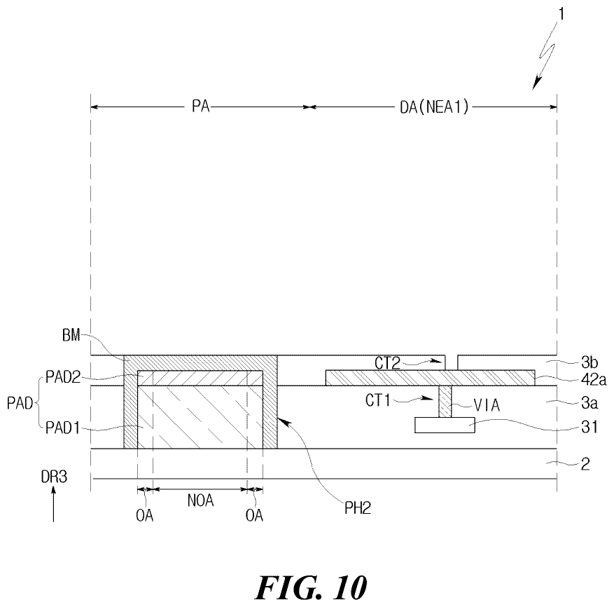

Referring to FIG. 10, the first reflective electrode 42a may be disposed on the first insulating layer 3a, and the second insulating layer 3b may be disposed on the first reflective electrode 42a. The first reflective electrode 42a may include the same material as the via VIA and may be formed by the same process, but is not limited thereto.

The second insulating layer 3b may be disposed to cover the pad PAD and the first reflective electrode 42a. The second insulating layer 3b may define the second contact hole CT2 exposing the first reflective electrode 42a in the first non-emission area NEA1 and define a second pad hole PH2 exposing the pad PAD and the periphery thereof in the pad area PA.

The light shielding layer BM may be formed in the second pad hole PH2. The light shielding layer BM may be disposed to fill the second pad hole PH2 and cover the pad PAD.

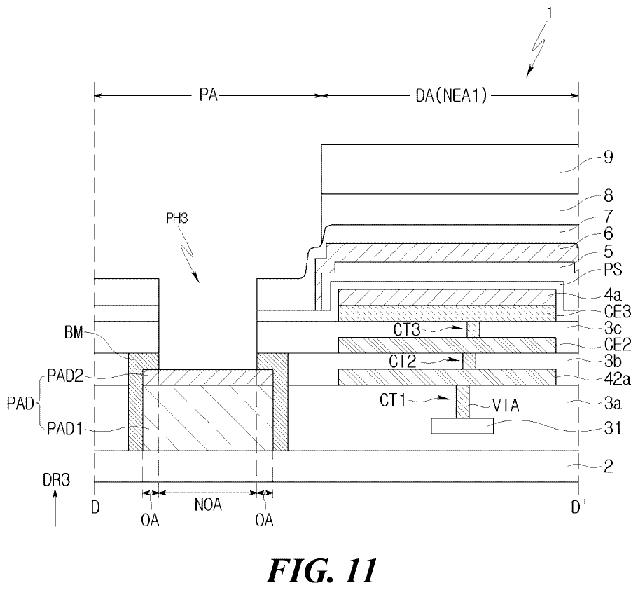

Referring to FIG. 11, the second connection electrode CE2, the third insulating layer 3c, the third connection electrode CE3, the first anode electrode 4a, the protective layer PS, the common emission layer 5, the cathode electrode 6, the capping layer 7, the encapsulation layer 8, and the color filter layer 9 may be sequentially stacked on the second insulating layer 3b in the display area DA.

At least some of the components stacked in the display area DA may be disposed together in the pad area PA.

A third pad hole PH 3 exposing the pad PAD may be formed in the pad area PA. The third pad hole PH 3 may be formed together with at least one of the second contact hole CT2, the third contact hole CT3, or may be formed by another process, but is not limited thereto.

The encapsulation layer 8 may be etched and removed by an etching laser in the pad area PA. During the process of etching the encapsulation layer 8, since the light shielding layer BM is disposed around the pad PAD, it is possible to suppress or prevent a lifting defect and tearing defect of the insulating film disposed between the plurality of pads PADs, thereby suppressing or preventing a short circuit defect that may occur between the pads PADs.

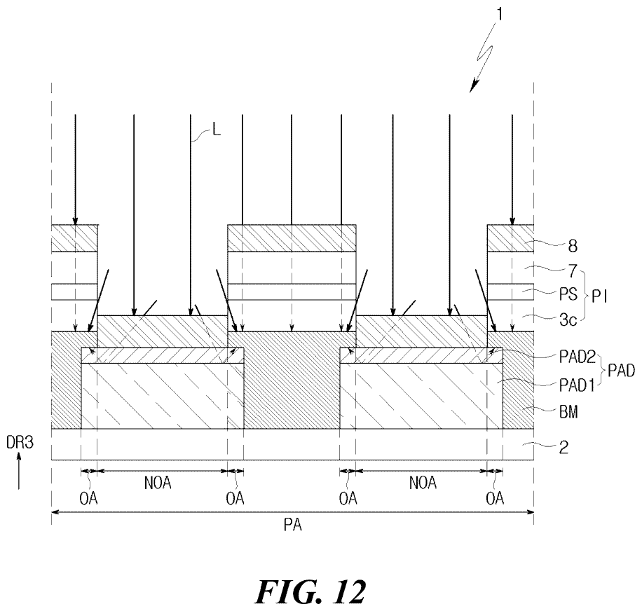

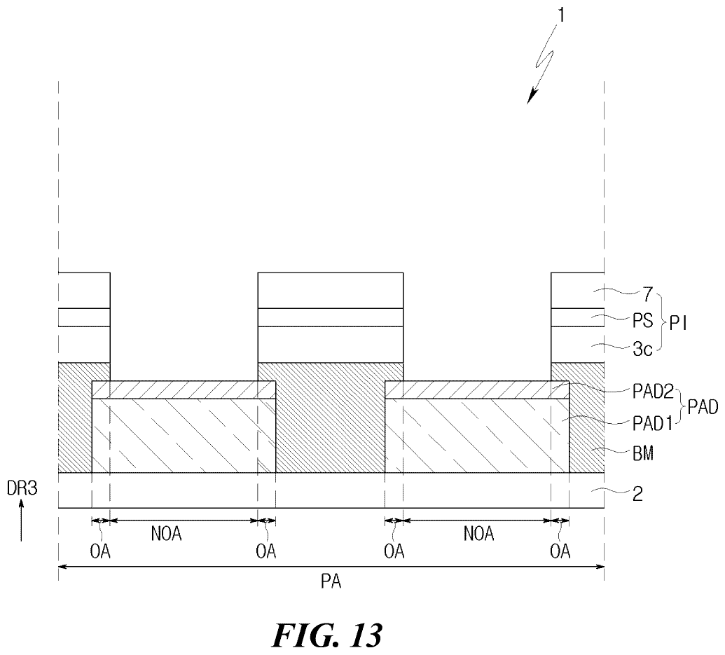

For detailed description thereof, FIGS. 12 and 13 are further referred to.

FIGS. 12 and 13 are cross-sectional views for describing a process of etching an encapsulation layer of a display apparatus according to one embodiment.

Referring to FIGS. 12 and 13, during the process of sequentially stacking the second connection electrode CE2, the third insulating layer 3c, the third connection electrode CE3, the first anode electrode 4a, the protective layer PS, the common emission layer 5, the cathode electrode 6, the capping layer 7, the encapsulation layer 8, and the color filter layer 9 on the second insulating layer 3b of FIG. 11, the encapsulation layer 8 may be disposed across the entire area of the pad area PA

The encapsulation layer 8 may be disposed both on the capping layer 7 and the pad PAD exposed by the third insulation layer 3c, the protective layer PS, and the capping layer 7. The encapsulation layer 8 disposed in the pad area PA may be etched and removed by an etching laser L.

The etching laser L may be reflected by the pad PAD between the pad PAD and the insulating film adjacent to the pad PAD. When the etching laser L is reflected between the pad PAD and the insulating film adjacent to the pad PAD, lifting or tearing may occur between the pad PAD and the insulating film adjacent to the pad PAD.

However, when the insulating film adjacent to the pad PAD is formed as the light shielding layer BM capable of absorbing and blocking the etching laser L, it is possible to suppress or prevent the etching laser L from penetrating between the pad PAD and the light shielding layer BM. Since the light shielding layer BM is disposed around the pad PAD, it is possible to prevent damage to the insulating film (the light shielding layer BM) adjacent to the pad PAD, thereby more smoothly maintaining the insulating film disposed between the plurality of pads PADs, and thus it is possible to suppress or prevent a short circuit defect that may occur between the plurality of pads PADS.

Furthermore, even when the encapsulation layer 8 has high transmittance, since the light shielding layer BM is disposed around the pad PAD, the insulating films (the light shielding layer BM and pad insulating layer PI) around the pad PAD can be maintained more smoothly. Accordingly, it is possible to suppress or prevent a short circuit defect between adjacent pads PADs.

Accordingly, it is possible to suppress or prevent an operation defect of the display apparatus 1 and extend the life of the display apparatus 1.

Hereinafter, other embodiments of the present specification will be described. For contents that are substantially the same as those described with reference to FIGS. 1 to 13 among components included in other embodiments, the same reference numerals are given, and overlapping contents may be omitted or briefly described.

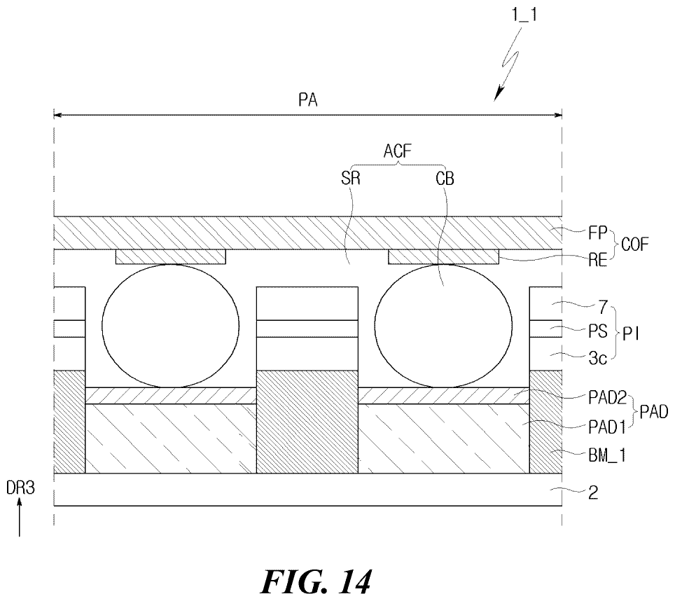

FIG. 14 is a cross-sectional view of a display apparatus according to yet another embodiment.

Referring to FIG. 14, a display apparatus 1_1 according to the present embodiment may include a plurality of pads PADs and a light shielding layer BM_1 disposed around the pad PAD, and the light shielding layer BM_1 may expose the entire area of the pad PAD.

Specifically, the light shielding layers BM_1s are disposed around the plurality of pads PADs. The light shielding layer BM _1 and the pad insulating layer PI may expose all areas of upper surfaces of the plurality of pads PADs (upper surfaces of the second pad layers PAD2s). Accordingly, the light shielding layer BM _1 and the pad insulating layer PI may not overlap the pad PAD.

In this case, since an area of the pad PAD that may come into contact with the conductive ball CB may increase, electrical connection between the pad PAD and the conductive ball CB can be smoother.

Even in this case, since the etching laser that etches the encapsulation layer 8 may be absorbed and blocked by the light shielding layers BM_1s disposed around the plurality of pads PADs, it is possible to suppress or prevent a lifting defect or tearing defect of the insulating films disposed around the plurality of pads PADs. Furthermore, it is possible to suppress or prevent the lifting defect or tearing defect of the insulating films disposed around the plurality of pads PADS, thereby suppressing or preventing an operation defect of the display apparatus 1_1 and extending the life of the display apparatus 1_1.

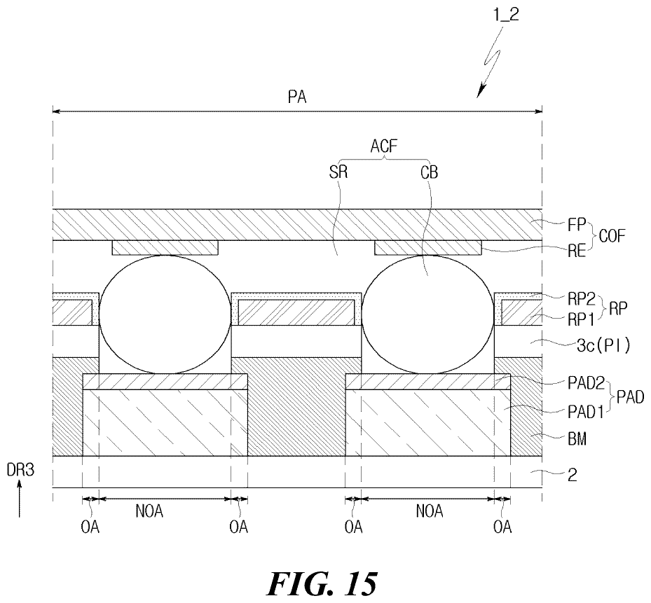

FIG. 15 is a cross-sectional view of a display apparatus according to yet another embodiment.

Referring to FIG. 15, a display apparatus 1_2 according to the present embodiment may include the plurality of pads PADs, the light shielding layer BM around the pad PAD, and the pad insulating layer PI and further include a reflective pattern RP on the pad insulating layer PI.

The reflective pattern RP may be disposed on the pad insulating layer PI in the pad area PA. The reflective pattern RP may include a reflective layer RP1 and an oxide film RP2 disposed on the reflective layer RP1.

The reflective layer RP1 may include a metal, but is not limited thereto. For example, the reflective layer RP1 may include aluminum (Al), but is not limited thereto. The oxide film RP2 may be formed by oxidizing a surface of the reflective layer RP1, but is not limited thereto. For example, when the reflective layer RP1 includes Al, the oxide film RP2 may include an aluminum oxide (AlₓO_{y}), but is not limited thereto.

The oxide film RP2 may cover all areas of upper surface and side surfaces of the reflective layer RP1. The reflective layer RP1 may not be exposed by the oxide film RP2. Even when the reflective layer RP1 includes a metal, the oxide film RP2 can suppress or prevent a short circuit that may occur between adjacent pads PADs due to the conductive ball CB and the reflective pattern RP.

Even in this case, since the etching laser that etches the encapsulation layer 8 may be absorbed and blocked by the light shielding layers BM s disposed around the plurality of pads PADS, it is possible to suppress or prevent a lifting defect or tearing defect of the insulating films disposed around the plurality of pads PADs. Furthermore, it is possible to suppress or prevent the lifting defect or tearing defect of the insulating films disposed around the plurality of pads PADs, thereby suppressing or preventing an operation defect of the display apparatus 1_2 and extending the life of the display apparatus 1_2.

In the display apparatus 1_2 of the present embodiment, the pad insulating layer PI may be formed as the third insulating layer 3c, but is not limited thereto. The reflective pattern RP may be disposed between the third insulating layer 3c of the pad insulating layer PI (see FIG. 8) and the protective layer PS according to one embodiment, and the insulating films disposed above the reflective pattern RP may be removed.

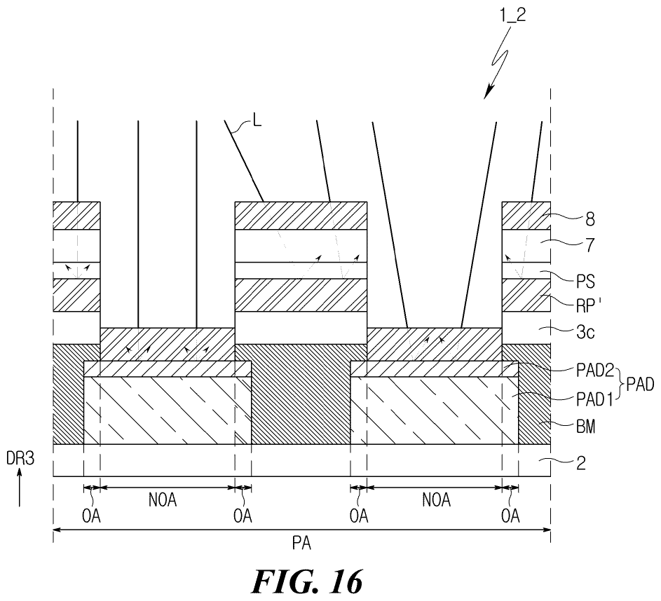

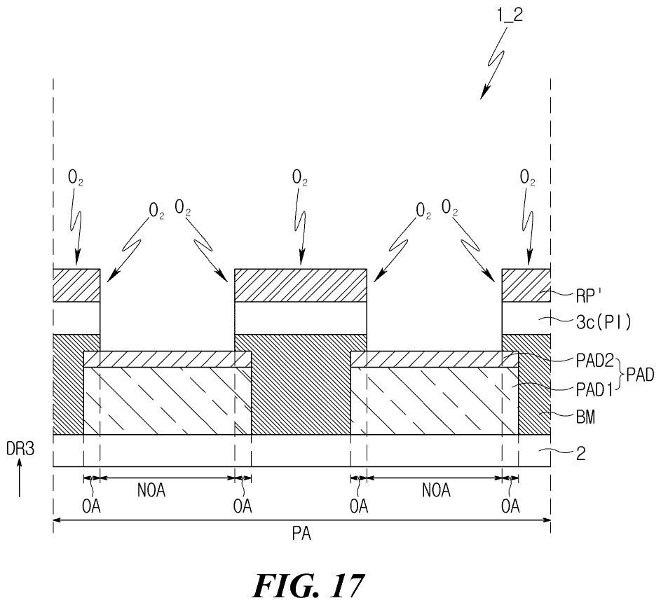

To describe this, FIGS. 16 and 17 are referred to.

FIGS. 16 to 18 are views illustrating a process of manufacturing the display apparatus according to the embodiment of FIG. 15.

Referring to FIG. 16, during the process of etching the encapsulation layer 8 by the etching laser L, a reflective pattern layer RP′ may be further disposed in the pad area PA. The reflective pattern layer RP′ may include a metal, but is not limited thereto. The metal may include, for example, Al, but is not limited thereto.

The reflective pattern layer RP′ may be disposed to overlap the light shielding layer BM. The reflective pattern layer RP′ may be disposed between the third insulating layer 3c and the protective layer PS, but is not limited thereto, and the stacking order of the reflective pattern layer RP′ may be diverse. For example, the reflective pattern layer RP′ may be disposed on the light shielding layer BM and the third insulating layer 3c or may be disposed between the protective layer PS and the capping layer 7.

The etching laser L may be reflected by the reflective pattern layer RP′ at the boundary between the reflective pattern layer RP′ and the protective layer PS. In this case, the protective layer PS may be removed from the reflective pattern layer RP′ by a tearing phenomenon, and the capping layer 7 and the encapsulation layer 8 that are disposed on the protective layer PS may also be removed together.

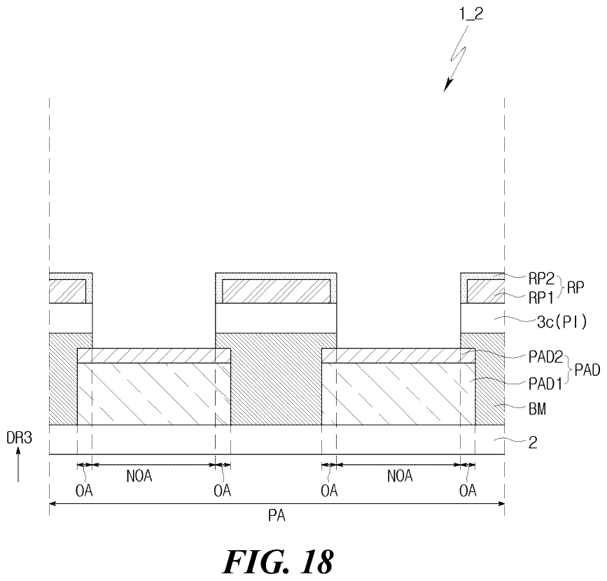

Referring further to FIGS. 17 and 18, a surface of the exposed reflective pattern layer RP′ may be oxidized by creating an oxygen atmosphere after the protective layer PS, the capping layer 7, and the encapsulation layer 8 are removed. Oxidation may occur on upper and side surfaces of the exposed reflective pattern layer RP′.

Accordingly, the reflective pattern RP may be formed by the reflective pattern layer RP′. The reflective pattern RP may include the reflective layer RP1 and the oxide film RP2. Since the oxide film RP2 is formed on the reflective layer RP1, even when the reflective layer RP1 includes a metal, it is possible to suppress or prevent a short circuit that may occur between adjacent pads PADs due to the conductive ball CB and the reflective pattern RP.

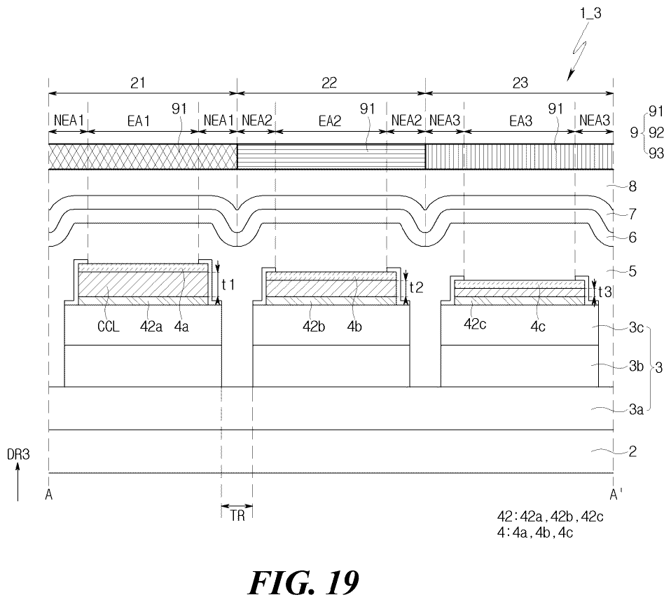

FIG. 19 is a cross-sectional view of a display apparatus according to yet another embodiment.

Referring to FIG. 19, a display apparatus 1_3 according to the present embodiment may further include a spacing maintenance layer CCL between the anode electrode layer 4 (4a, 4b, and 4c) and the reflective electrode 42 (42a, 42b, and 42c).

The spacing maintenance layer CCL may have a different thickness for each sub-pixel 21, 22, or 23. For example, a first thickness t1 of the spacing maintenance layer CCL disposed between the first reflective electrode 42a and the first anode electrode 4a in the first sub-pixel 21 may be greater than a second thickness t2 of the spacing maintenance layer CCL disposed between the second reflective electrode 42b and the second anode electrode 4b in the second sub-pixel 22. The second thickness t2 may be greater than a third thickness t3 of the spacing maintenance layer CCL disposed between the third reflective electrode 42c and the third anode electrode 4c in the third sub-pixel 23.

The reflective electrode 42 (42a, 42c, and 42c) may be disposed on the same layer. The reflective electrode 42 (42a, 42c, and 42c) may be disposed on the third insulating layer 3c.

Even when the reflective electrode 42 (42a, 42c, and 42c) is disposed on the same layer, since the spacing maintenance layer CCL is disposed with a different thickness for each sub-pixel 21, 22, or 23, it is possible to further increase light extraction efficiency using the micro-cavity characteristic.

Even in this case, the light shielding layers B Ms (see FIG. 8) may be disposed around the plurality of pads PADs (see FIG. 8). Since the light shielding layers BM s (see FIG. 8) disposed around the plurality of pads PADs (see FIG. 8) may absorb and block the etching laser that etches the encapsulation layer 8, it is possible to suppress or prevent a lifting defect or tearing defect of the insulating films disposed around the plurality of pads PADs (see FIG. 8). Furthermore, it is possible to suppress or prevent the lifting defect or tearing defect of the insulating films disposed around the plurality of pads PADs (see FIG. 8), thereby suppressing or preventing an operation defect of the display apparatus 1_3 and extending the life of the display apparatus 1_3.

In addition, since the micro-cavity characteristics may be exhibited in various ways according to the configuration and process of the display apparatus 1_3, it is possible to optimize the configuration and process of the display apparatus 1_3.

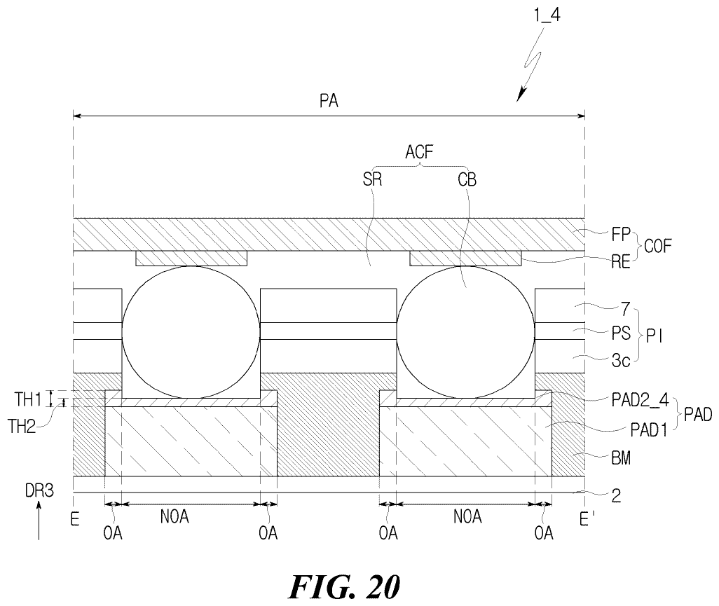

FIG. 20 is a cross-sectional view of a display apparatus according to yet another embodiment.

Referring to FIG. 20, a display apparatus 1_4 according to the present embodiment includes the plurality of pads PADs and the light shielding layer BM around the pad PAD. A part of an upper portion of the pad PAD of the present embodiment may be over-etched.

The pads PAD may have different thicknesses in the overlapping area OA and the non-overlapping area NOA. The thickness of the pad PAD that does not overlap the light shielding layer BM may be smaller than the thickness of the pad PAD that overlaps the light shielding layer BM. That is, the thickness of the pad PAD in the non-overlapping area NOA may be greater than the thickness of the pad PAD in the overlapping area OA.

During the process of etching the encapsulation layer 8 (see FIG. 12), a part of the pad PAD that does not overlap the light shielding layer BM may be etched together by the etching laser L (see FIG. 12), and a thickness of a part of the pad PAD that does not overlap the light shielding layer BM may be decreased.

In this case, a part of a second pad layer PAD2_4, which is disposed in the non-overlapping area NOA, may be etched. For example, a first thickness TH1 of the second pad layer PAD2_4 in the overlapping area OA may be greater than a second thickness TH2 of the second pad layer PAD2_4 in the non-overlapping area NOA.

However, the embodiments of the present specification are not limited thereto, and when the second pad layer PAD2_4 is etched to expose the first pad layer PAD1 in the non-overlapping area NOA, a part of the first pad layer PAD1 may also be etched together.

As a part of the pad PAD is over-etched, surface roughness of the over-etched part of the pad PAD may be more than surface roughness of the non-over-etched remainder of the pad PAD. Upper surface roughness of the non-overlapping area NOA may be more than upper surface roughness of the pad PAD in the overlapping area OA.

In this case, upper surface roughness of the second pad layer PAD2_4 in the non-overlapping area NOA may be greater than the upper surface roughness of the second pad layer PAD2)4 in the overlapping area OA.

Even in this case, since the etching laser that etches the encapsulation layer 8 may be absorbed and blocked by the light shielding layers B Ms disposed around the plurality of pads PADS, it is possible to suppress or prevent a lifting defect or tearing defect of the insulating films disposed around the plurality of pads PADs. Furthermore, it is possible to suppress or prevent the lifting defect or tearing defect of the insulating films disposed around the plurality of pads PADs, thereby suppressing or preventing an operation defect of the display apparatus 1_4 and extending the life of the display apparatus 1_4.

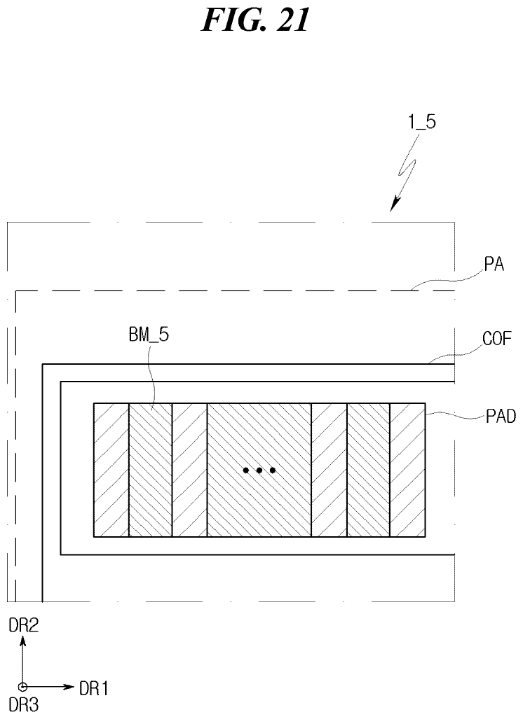

FIG. 21 is an enlarged view of a pad area of a display apparatus according to yet another embodiment.

Referring to FIG. 21, a display apparatus 1_5 according to the present embodiment may include the plurality of pads PADs and a light shielding layer BM_5 disposed around the pad PAD, and the light shielding layer BM_5 may be formed of a plurality of separation patterns.

The light shielding layer BM_5 formed of the plurality of separation patterns may be disposed between adjacent pads PADs. The light shielding layer BM_5 is described as not overlapping the pad PAD, but is not limited thereto, and the light shielding layer BM_5 may be formed to overlap at least a part of the pad PAD.

The light shielding layer BM_5 may be disposed across all areas between adjacent pads PADs. The light shielding layer BM_5 may cover all of opposing side surfaces of adjacent pads PADs. A length of the light shielding layer BM_5 in the second direction DR2 may be equal to or larger than a length of the pad PAD in the second direction DR2, but is not limited thereto.

Even in this case, since the etching laser L (see FIG. 12) that etches the encapsulation layer 8 (see FIG. 12) may be absorbed and blocked by the light shielding layers BM s disposed around the plurality of pads PADs, it is possible to suppress or prevent a lifting defect or tearing defect of the insulating films disposed around the plurality of pads PADs. Furthermore, it is possible to suppress or prevent the lifting defect or tearing defect of the insulating films disposed around the plurality of pads PADs, thereby suppressing or preventing an operation defect of the display apparatus 1_5 and extending the life of the display apparatus 1_5.

In addition, since only a minimum light shielding layer BM for preventing a short circuit defect between adjacent pads PADs may be disposed, it is possible to minimize the process cost and the process time, thereby enabling process optimization.

A display apparatus according to various embodiments of the present specification may be described as follows.

A display apparatus according to embodiments of the present disclosure includes a substrate including a display area including a plurality of sub-pixels and a pad area located around the display area, a pad disposed on the substrate in the pad area and provided as a plurality of pads, and a light shielding layer disposed between a plurality of adjacent pads.

According to various embodiments of the present specification, a pad insulating layer may be further disposed on the light shielding layer.

According to various embodiments of the present specification, the sub-pixel may include an insulating layer on the substrate, a reflective electrode on the insulating layer, an anode electrode on the reflective electrode, and a bank on the anode electrode.

According to various embodiments of the present specification, the insulating layer may include the same material as the pad insulating layer.

According to various embodiments of the present specification, a sub-pixel may include an emission area and a non-emission area around the emission area, and in the emission area, the bank may partially expose an upper surface of the anode electrode.

According to various embodiments of the present specification, the bank may overlap the light shielding layer.

According to various embodiments of the present specification, the sub-pixel may further include a transistor disposed in the insulating layer of the non-emission area, and the transistor may be electrically connected to the reflective electrode through a via.

According to various embodiments of the present specification, the pad may include a first pad layer, and a second pad layer having a different material from the first pad layer.

According to various embodiments of the present specification, the first pad layer may have the same material as the via.

According to various embodiments of the present specification, the display apparatus may further include a reflective pattern overlapping a pad insulating layer.

According to various embodiments of the present specification, the reflective pattern may further include a reflective layer and an oxide film formed on a surface of the reflective layer.

According to various embodiments of the present specification, the light shielding layer may come into direct contact with side surfaces of the plurality of adjacent pads.

According to various embodiments of the present specification, a part of the light shielding layer may overlap the plurality of adjacent pads.

According to various embodiments of the present specification, the light shielding layer may not overlap the plurality of adjacent pads.

According to various embodiments of the present specification, there is provided a display apparatus including a substrate including a pad area, a plurality of pads disposed on the substrate in the pad area, a light shielding layer disposed around the plurality of pads in the pad area, a flexible film including a lead electrode overlapping the plurality of pads and electrically connected to the plurality of pads, and an anisotropic conductive film disposed between the substrate and the flexible film, in which the anisotropic conductive film comes into direct contact with the light shielding layer.

According to various embodiments of the present specification, the light shielding layer may come into direct contact with side surfaces of the plurality of adjacent pads.

According to various embodiments of the present specification, a part of the light shielding layer may overlap the plurality of adjacent pads.

According to various embodiments of the present specification, the light shielding layer may not overlap the plurality of adjacent pads.

According to some embodiments of the present specification, the display apparatus may further include a pad insulating layer disposed on the light shielding layer.

According to some embodiments of the present specification, the display apparatus may further include a reflective pattern disposed on the pad insulating layer.

Although the embodiments have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus
2: substrate
3: insulating layer
4: anode electrode layer
5: common emission layer
6: cathode electrode
7: capping layer
8: encapsulation layer
9: color filter layer
BM: light shielding layer
OA: overlapping area
NOA: non-overlapping area
PAD: pad
PA: pad area
PI: pad insulating layer

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a display area including a plurality of pixels, and a pad area adjacent to the display area;
a pad on the substrate in the pad area and provided as a plurality of pads; and
a light shielding layer between adjacent pads of the plurality of pads.

2. The display apparatus of claim 1, further comprising a pad insulating layer on the light shielding layer.

3. The display apparatus of claim 1, wherein the sub-pixel includes:
an insulating layer on the substrate;
a reflective electrode on the insulating layer;
an anode electrode on the reflective electrode, and a bank on the anode electrode.

4. The display apparatus of claim 3, wherein the insulating layer includes the same material as a pad insulating layer on the light shielding layer.

5. The display apparatus of claim 3, wherein the sub-pixel includes an emission area, and a non-emission area adjacent to the emission area, and
wherein in the emission area, the bank partially exposes an upper surface of the anode electrode.

6. The display apparatus of claim 5, wherein the bank overlaps the light shielding layer.

7. The display apparatus of claim 5, further comprising a via,
wherein the sub-pixel further includes a transistor disposed in the insulating layer of the non-emission area, and
wherein the transistor is electrically connected to the reflective electrode through the via.

8. The display apparatus of claim 7, wherein the pad includes a first pad layer, and a second pad layer having a different material from the first pad layer.

9. The display apparatus of claim 8, wherein the first pad layer has the same material as the via.

10. The display apparatus of claim 2, further comprising a reflective pattern overlapping the pad insulating layer.

11. The display apparatus of claim 10, wherein the reflective pattern further includes a reflective layer, and an oxidation film on a surface of the reflective layer.

12. The display apparatus of claim 1, wherein the light shielding layer comes into direct contact with side surfaces of the plurality of adjacent pads.

13. The display apparatus of claim 1, wherein a part of the light shielding layer overlaps the adjacent pads.

14. The display apparatus of claim 1, wherein the light shielding layer does not overlap the adjacent pads.

15. A display apparatus comprising:
a substrate including a pad area;
a plurality of pads on the substrate in the pad area;
a light shielding layer around the plurality of pads in the pad area;
a flexible film including a lead electrode overlapping the plurality of pads and electrically connected to the plurality of pads; and
an anisotropic conductive film between the substrate and the flexible film,
wherein the anisotropic conductive film comes into direct contact with the light shielding layer.

16. The display apparatus of claim 15, wherein the light shielding layer comes into direct contact with side surfaces of adjacent pads of the plurality of pads.

17. The display apparatus of claim 15, wherein a part of the light shielding layer overlaps the adjacent pads.

18. The display apparatus of claim 15, wherein the light shielding layer does not overlap the adjacent pads.

19. The display apparatus of claim 15, further comprising a pad insulating layer on the light shielding layer.

20. The display apparatus of claim 19, further comprising a reflective pattern on the pad insulating layer.
